(19) United States
(12) Patent Application Publication
(10) Pub. No.: US 2011/0002494 A1
(43) Pub. Date: Jan. 6, 2011

(54) Housing for an Electrically Operated Device

(75) Inventor: Hans-Peter Opitz, Ratingen (DE)

Correspondence Address: PRIEST & GOLDSTEIN PLLC, 5015 SOUTHPARK DRIVE, SUITE 230, DURHAM, NC, 27713-7736, US

(73) Assignee: FHF Funke + Huster Femsig GmbH, Mulheim an der Ruhr (DE)

(21) Appl. No.: 12/063,690

(22) PCT Filed: Aug. 18, 2006
(86) PCT No.: PCT/EP06/08153

§ 371 Date: Aug. 25, 2010

(30) Foreign Application Priority Data
Sep. 8, 2005 (DE) 10 2005 042 565.8

(51) Int. Cl. H04R 1/02; H05K 5/02; H01L 23/06

(52) U.S. Cl. 381/334; 174/520; 174/565; 427/227

(57) ABSTRACT

The invention relates to a housing for an electrically-operated device, said housing being located in an environment subject to the risk of explosion. The housing is made from a material which is gas-permeable and non-flammable. Metal foam is an example of a suitable material.

Loudspeakers or other electrically operated devices supplied with electric energy must be protected in special ways in environments subject to the hazard of explosions. An especially frequently encountered protection comprises the explosion-protected type of construction “flame-proof enclosure” which permits operating a loudspeaker in a dangerous gas atmosphere. Advanced versions of the “flame-proof or pressure-resistant enclosure” are made possible through the new European Standard IEC 60079-1:2003 (EN 60079-1:03.2004).

In the ignition protection type “flameproof encapsulation d” the ignition of an explosion in the interior of a piece of equipment is possible and permitted, however, the pressure resistance property or burst strength must ensure that the housing is not destroyed. Furthermore, the explosion must not be allowed to propagate into the surrounding atmosphere through construction-dependent openings in the housing. The explosions must be so-to-speak locked up through a suitable realization of gap openings, in order for the explosion not to spread into the potentially explosive environment (D. Markus, U. Klausmeyer, F. Engelmann and A. Hillinger: Neue Materialien in der Druckfesten Kapselung, Ex-Zeitschrift 2004, pp. 52-56).

A method for conducting explosion gases formed within the interior of an explosion-protected housing is already known, in which method the quantity of the gases entering into gaps of the housing is reduced through flow dividers (DE 198 26 911 C2). Instead of flow dividers, it is also feasible to provide relief openings provided with flame barriers.

In another known protective housing for the pressure resistant enclosure of electrical equipment a connecting passage for cooling water is provided, in this channel a pressure resistant barrier being disposed (DE 101 52 510 B4). The pressure resistant barrier comprises here a multiplicity of outlet channels whose cross sectional and longitudinal dimensions are such that an ignition breakthrough from the interior of the housing through the barrier to the outside is prevented.

Furthermore is known a closed explosion-protected housing for housing electrical components, which housing has an opening closed by means of a porous closure plug (EP 0 157 285 B1).

In another electrical circuitry installation in an explosion-protected type of construction a disk of a porous material is provided as a pressure balancing means (DE 84 09 870.8 U). Such a disk is, for example, a porous ceramic disk, a sintered filter or a narrow-mesh wire lattice.

In the known installations and arrangements comprising porous material, only some parts are comprised of this material, while other parts are comprised of conventional material.

The invention addresses the problems of disposing entire component assemblies in a space subject to the hazard of explosions such that explosions potentially generated in the assemblies do not spread out.

The invention consequently relates to a housing for an electrically operated device, this housing being located in an environment subject to the hazard of explosions. This housing is comprised of a material which is gas permeable and non-combustible. The material to be considered as suitable is, for example, metal foam.

The advantage attained with the invention comprises in particular that the pressure jump in the event of an explosion taking place in a housing is attenuated through the housing itself.

Thus, already ignited, and also still to be ignited, gas or a gas mixture within a closed housing is conducted through open-celled walls of a housing to the outside, distributed here and cooled off. Ignition of the atmosphere outside of the housing is hereby avoided. The gas fractions still in the housing during the explosion and not yet consumed are also displaced on all sides toward the outside such that they can no longer participate in the explosion.

An embodiment example of the invention is shown in the drawings and will be described in the following in further detail. In the drawing depict:

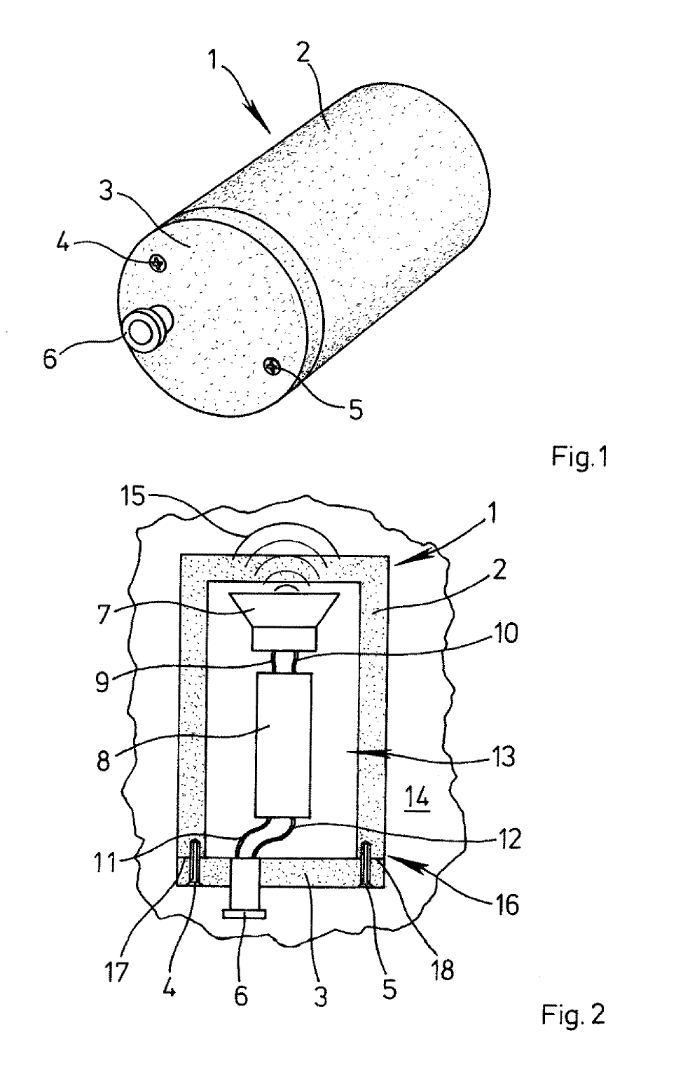

FIG. 1 a cylindrical housing of porous open-celled material;

FIG. 2 a section through the housing according to FIG. 1;

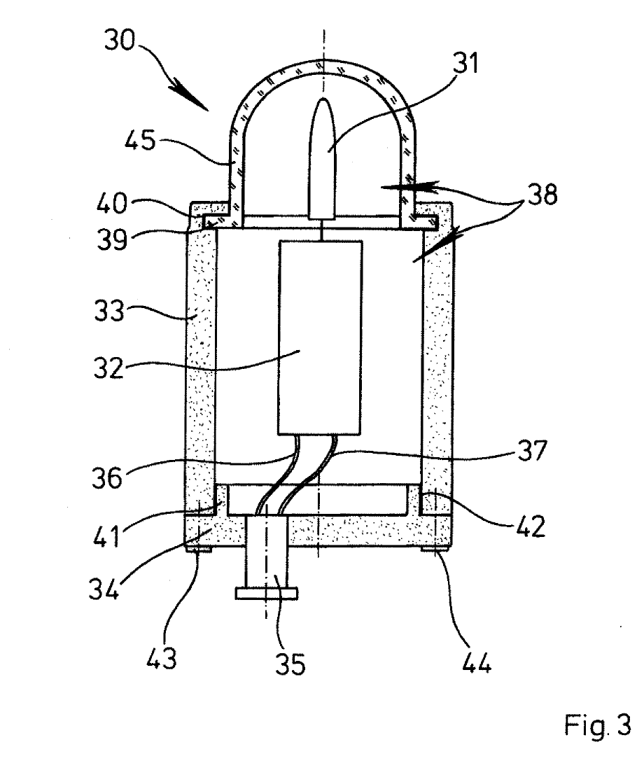

FIG. 3 a luminaire with a pressure-resistant housing.

FIG. 1 shows a cylindrical housing 1 comprising a cylindrical part 2, which part is closed with a cover 3. The cylindrical part 2 and the cover 3 are comprised of a porous open-celled material, for example of sintered metal or a metal foam. The cover 3 is connected with the cylindrical part 2 by means of two threaded fasteners 4, 5. It is understood that, instead of two threaded fasteners, several threaded fasteners can also be provided. On the cover 3 is provided a connection 6 for the supply of an electric voltage.

FIG. 2 shows a longitudinal section through the housing 1. It can be seen that in the interior of the housing 1 is located a loudspeaker 7 which is connected via lines 9, 10 with an electrical component 8. The component 8 itself is connected with connection 6 via lines 11, 12. The pressure-resistant interior volume 13 of housing 1 is consequently separated from the explosion-endangered outer surroundings 14 through housing 1. Sound waves 15 indicate that the material of the cylindrical part 2 is transmissible to sound. Instead of a loudspeaker, other sound generators, for example bells or other electrically operated devices, can also be provided.

In order for the sound waves 15 to be able to penetrate to the outside in a largely unattenuated manner, the material thickness, pore size and density must be appropriately optimized. However, this must be done exclusively taking into consideration the already described functionalities of the explosion protection. The method for the determination of the pore size and density are defined in ISO 4003 and ISO 4892. The safe wall thickness as a function of the pore size must be demonstrated according to IEC 60079-1:2003 (EN 60079-1:03.2004).

The material can be aluminum- or nickel foam or steel foam. The production methods for metal foams are divided into melt and powder metallurgical methods as well as into coating methods. Aluminum foams are known for example by the names Duocel, Alporas and Formgrip, while nickel- or nickel-chromium foams are known by the name Incofoam. The porosity can be open or closed. Duocel has an open porosity of 88% to 98%. Incofoam also has an open porosity of 91% to 98%. In contrast, Alporas has a closed porosity of 91% to 93%.

If, in the component 8, which inter alia can include an amplifier, or between the lines 9, 10, a shortcircuit occurs, first, portions of the gas within the interior space 13 are ignited. This generates a pressure jump in the interior space 13. This pressure jump causes the gases within the interior space 13 of housing 1 to be pressed into the outer space 14 through the porous open-celled walls of housing 1. Thus already during the explosion, an explosion pressure reduction takes place, this release taking place relatively rapidly since the gases are pressed to the outside through virtually the entire inner surface of the housing 1. The material of which the housing is comprised has, moreover, a cooling effect onto the escaping gases, which is so great that the ignition temperature of the gas in the outer space 14 is not reached.

In the separation plane 16 between the cylindrical part 2 and the cover 3 is located an interface gap 17, 18 which can be realized as an adhesion gap according to standards IEC 60079-1:2003 (EN 60079-1:03.2004).

FIG. 3 shows a flash lamp 30 comprising a flash tube 31 with a glass calotte 45 encompassing it. The flash tube 31 is connected with an electrical mounting component 32 enclosed in the vertical direction by a cylindrical housing 33 having a cover 34 on its bottom side. By 35 is denoted a cable entry point from which lead electrical lines 36, 37 to the mounting component 32. The glass calotte 45, the cover 34 and the housing 33 form a pressure-resistant chamber 38. The normative known ignition puncture-proof gap is here also determined by the shape and size of the pores. The glass calotte 45 has at the lower end an annular horizontal extension 39, between which and the housing 33 a firmly adhering seam site 40 is located. Cover 34 has an extension 41 directed into the chamber 38, with a junction 42 being formed between this extension 41, the cover 34 and the housing 33. The cover 34 is connected with threaded fasteners 43, 44 with the housing 33.

Housing 33 and cover 34 are comprised of foamed, pressed or porous open-celled materials. If, for example, a metal foam is utilized, such can be produced thereby that a cross-linked polyurethane foam is coated with nickel and subsequently the polyurethane is removed through thermal decomposition. The nickel can subsequently be optionally converted into a nickel-chromium alloy.

As housing material can also be utilized SRSS iron (SRSS=Schlicker reaction foam sinter) with a fraction of at least 15% chromium. The foaming is herein generated through a chemical reaction which proceeds at ambient temperature.

First are mixed the solid components, a metal powder and a dispersion agent, for example a laminated silicate. As a function of the alloy content of the metal powder, a blowing agent in the form of a very fine reactive metal powder, for example carbonyl iron, is added. Subsequently concentrated phosphoric acid is added to the solvent, water and/or alcohol, the acid dissociating in water. After the solid and the liquid components have been mixed, a slurry-like suspension is formed in which proceed two parallel reactions.

In the chemical reaction between the pure metal particulates and the acid, for one, hydrogen bubbles are formed, which cause the direct foaming of the slurry and, for example, a metal phosphate is formed which assumes the task of a bonding agent leading to the solidification of the foam structure. The foam structure is initially a closed-cell structure and only during the evaporation of the solvent is an open-celled structure obtained. The green body obtained in this way is sintered under reducing atmosphere to form an open-celled metal foam.

The mounting component 32 can be an ignition source for a gas mixture in the pressure-resistant chamber 38. In the event of an internal explosion there is no build-up of the maximum reference pressure but rather an immediate reduction of the explosion pressure occurs, since the device walls are permeable to gas.

By the designation that the housing encompasses at least the electrical component is understood not only a housing encompassing it on all sides, but rather, as FIG. 3 shows, also encasing it in only one direction. In the example of FIG. 3, this direction is the vertical direction. However, such could also be the horizontal direction. The critical issue is only that the electrical component 8, 32 does not project from the housing.

1. Housing for an electrically operated device suitable for use in an environment subject to the hazard of explosions, characterized in that the electrically operated device is a loudspeaker (7) connected to an electric component (8), wherein the loudspeaker (7) and the electric component (8), with the exception of an electric connection (6), are completely encompassed by a housing (1) comprised of a gas-permeable, however non-combustible, material.

2. Housing for an electrically operated device suitable for use in an environment subject to the hazard of explosions, characterized in that the electrically operated device is a light source (30) provided with an electric component (32), wherein all structural elements of the light source, with the exception of a glass calotte (45) of the light source (30) and an electric connection (6), are encompassed by a housing (33) comprised of a gas-permeable, however non-combustible, material.

3. Housing as claimed in claim 1 or claim 2, characterized in that the material is an open-celled porous material.

4. Housing as claimed in claim 1 or claim 2, characterized in that the material is comprised of sinter metal.

5. Housing as claimed in claim 1 or claim 2, characterized in that the material is comprised of SRSS iron with at least 15% chromium.

6. Housing as claimed in claim 1 or claim 2, characterized in that the housing is comprised of metal foam.

7. Housing as claimed in claim 1, characterized in that the housing (1) includes a cylindrical body (2) and a cover (3).

8. Housing as claimed in claim 1, characterized in that in the cover (3) is provided a feed connection (6) for electric energy.

9. Housing as claimed in claim 1, characterized in that the cover (3) is connected by threaded fasteners with the cylindrical body (2).

10. Housing as claimed in claim 2, characterized in that the light source (30) includes a flash tube (31).

11. Housing as claimed in claims 2 and 10, characterized in that the flash tube (31) is encompassed by the glass calotte (45) which includes at its lower margin an annular concentric extension (39), the housing (33) terminating over this extension (39).

12. Method for the production of a metal foam as claimed in claim 6, characterized in that a cross-linked polyurethane foam is coated with nickel, subsequently the polyurethane is removed by thermal decomposition and hereupon the nickel is converted into a nickel-chromium alloy.

13. Method as claimed in claim 12, characterized in that the conversion of the nickel into a nickel-chromium alloy takes place through diffusion out of the gas phase.

14. Method as claimed in claim. 2, characterized in that the metal foam is densified.
